(19) United States
(12) Patent Application Publication
(10) Pub. No.: US 2008/0074914 A1
(43) Pub. Date: Mar. 27, 2008

(54) MEMORY DEVICES WITH SENSE AMPLIFIERS

(75) Inventors: Hong-Gee FANG, YILAN (TW); Wen-Chieh LEE, HSINCHU CITY (TW); Ching-Wen CHEN, Hsinchu City (TW); Chih-Yuan CHENG, Hsinchu City (TW); Chung-Cheng WU, Hsinchu City (TW)

Correspondence Address: Akin Gump LLP - Silicon Valley, 3000 El Camino Real, Two Palo Alto Square, Suite 400, Palo Alto, CA, 94306, US

(73) Assignee: MEMOCOM CORP., Hsinchu City (TW)

(21) Appl. No.: 11/859,721

(22) Filed: Sep. 21, 2007

Related U.S. Application Data
(60) Provisional application No. 60/846,560, filed on Sep. 21, 2006.

(51) Int. Cl. G11C 5/02; G11C 7/02

(52) U.S. Cl. 365/63; 365/207

(57) ABSTRACT

A memory device comprises a first memory cell and a second memory cell. The first memory cell includes a first transistor coupled to a bit line and the second memory cell includes a second transistor coupled to a bit line bar. The first transistor includes a first gate terminal coupled to a first word line. The second transistor includes a second gate terminal coupled to a second word line. The first transistor and the second transistor are controlled by the first word line and the second word line respectively. A first sense amplifier having an asymmetric configuration is coupled to the bit line and the bit line bar and is capable to sense a status of at least one of the bit line and the bit line bar.

### RELATED APPLICATION

This application is related to and hereby claims the priority benefit of U.S. Provisional Patent Application No. 60/846,560, filed Sep. 21, 2006, incorporated herein by reference in its entirety.

### TECHNICAL FIELD

This application relates generally to sense amplifiers associated with memory devices.

### BACKGROUND

Sensing amplifiers have been widely used in various memory arrays. As an example, each memory cell in a memory array may have an output to indicate the status of the cell. Using a random access memory as an example, each memory cell may have its output connected to one of two bit lines, BL (Bit Line) or BLB (Bit Line Bar). Prior to a memory read operation, the two bit lines may be pre-charged to a reference voltage, which is typically between the high voltage (e.g., VDD) and ground. During the read operation, which connects a bit line or bit line bar to a memory cell, the charges stored in a memory cell may change the voltage level of the bit line. After the read operation, the bit line and the bit line bar may have two different voltage levels.

A sense amplifier may be used to read the result of a read operation. For example, a sense amplifier may be connected to the two bit lines to sense a voltage difference and to amplify the difference to read out the cell status, such as a logic 0 or logic 1. As an example, a sense amplifier may have a symmetric inverter pair, which has two identical inverters that are crossly-coupled. In other words, inverters in the sense amplifier have the same characteristics and are used for both BL sensing and BLB sensing. With this sense amplifier design, the reference voltage is usually set at VDD/2.

FIG. 1(a) illustrates a prior art example of a memory device and an accompanying sensing circuit. Referring to FIG. 1(a), the memory device has two memory cells 110 and 115, pre-charge circuit 140, and sense amplifier 150. Memory cell 110 may be written by selectively enabling word line (WL) 120 and may be read via bit line (BL) 130. Similarly, memory cell 115 may be written by selectively enabling word lines (WL) 125 and may be read via bit line bar (BLB) 135.

In a read operation, a pre-charge circuit 140 will be enabled by its control signal PRCH 145 so that the pre-charge circuit 140 may pre-charge both BL 130 and BLB 135 to a reference voltage VPR as illustrated in FIG. 1(b). The voltage VPR is VDD/2, one half of VDD, which may be a positive voltage level provided by a common power supply terminal of the memory device. After the pre-charge process 176, a voltage, such as VDD, may be applied to a word line 120 to read a corresponding memory cell. In reading memory cell 110, it may store a level of charge representing a logic “1” or logic “0”, which may correspond to a voltage level of or near VDD or ground, respectively. Depending on the charge stored, the bit line 130, once coupled to the memory cell 110, may be charged to a higher voltage or discharged to a lower voltage from its initial pre-charged status of VDD/2 during the charge sharing process 177 shown in FIG. 1(b).

After the read operation, the sense amplifier 150, which is enabled by a control signal SNR 175, will amplify the signals from the two bit lines, BL 130 and BLB 135. Thus, the sensing process 178 starts as illustrated in FIG. 1(b). As shown in FIG. 1(c) and FIG. 1(d), an example of a sense amplifier is illustrated. The sense amplifier 150 may include two inverters of the same type and characteristics, which provide a symmetric configuration. Accordingly, the trip point 188 of the inverter 180 and the trip point 190 of the inverter 182 in FIG. 1(c) and FIG. 1(d) are identical as shown in FIG. 1(e).

### BRIEF SUMMARY

In various embodiments of the invention, a memory device includes at least one sense amplifier with an asymmetrical configuration.

In one embodiment, a memory device comprises a first memory cell and a second memory cell, wherein the first memory cell comprises a first transistor coupled to a bit line and the second memory cell comprises a second transistor coupled to a bit line bar. The gate terminals of the first transistor and the second transistor may be coupled to and controlled by a first word line and a second word line respectively. A first sense amplifier may be coupled to the bit line and the bit line bar and has an asymmetric configuration. The sense amplifier may be configurable to sense a status of at least one of the bit line and the bit line bar.

### BRIEF DESCRIPTION OF THE DRAWINGS

The embodiments illustrated in the figures of the accompanying drawings herein are by way of example and not by way of limitation.

FIG. 1(a) illustrates an example of a memory device and an accompanying sensing circuit of the prior art.

FIG. 1(b) is an exemplary waveform to illustrate the operation of a memory device of the prior art.

FIGS. 1(c) and 1(d) illustrate an example of a sense amplifier of the prior art.

FIG. 1(e) illustrates the characteristics of two similarly configured inverters of the prior art.

FIG. 2 illustrates a block diagram of memory array device according to one embodiment of the invention.

FIG. 3 illustrates an exemplary memory device according to one embodiment of the invention.

FIG. 4(a) illustrates a block diagram of one configuration of sensing amplifiers according to an embodiment of the invention.

FIG. 4(b) illustrates an example of the transfer characteristic functions of two inverters in a sense amplifier according to an embodiment of the invention.

FIG. 4(c) illustrates an example of the transfer characteristic functions of two inverters in another sense amplifier according to an embodiment of the invention.

FIG. 5(a) illustrates a block diagram of another configuration of sensing amplifiers according to an embodiment of the invention.

FIG. 5(b) illustrates an example of the transfer characteristic functions of two inverters in a sense amplifier according to an embodiment of the invention.

FIG. 5(c) illustrates an example of the transfer characteristic functions of two inverters in another sense amplifier according to an embodiment of the invention.

FIG. 6 illustrates an exemplary waveform for illustrating the sense amplifier operation according to an embodiment of the invention.

FIG. 7 illustrates another exemplary waveform for illustrating the sense amplifier operation according to an embodiment of the invention.

FIG. 8 illustrates example waveforms of BL and BLB when a memory cell stores a logic “0,” according to an embodiment of the invention.

FIG. 9 illustrates example waveforms of BL and BLB when a memory cell stores a logic “1,” according to an embodiment of the invention.

FIG. 10 illustrates an example of providing an asymmetric sense amplifier by sharing some of the transistors according to an embodiment of the invention.

FIG. 11 illustrates another example of providing an asymmetric sense amplifier by sharing some of the transistors according to an embodiment of the invention.

FIG. 12 illustrates an example of a circuit for controlling the enabling of sense amplifiers according to an embodiment of the invention.

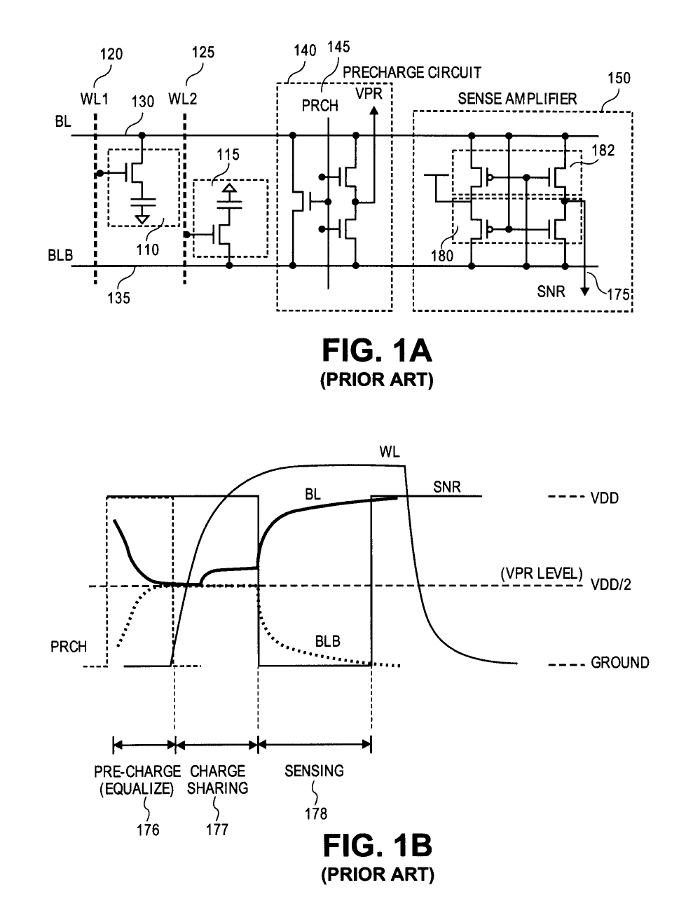

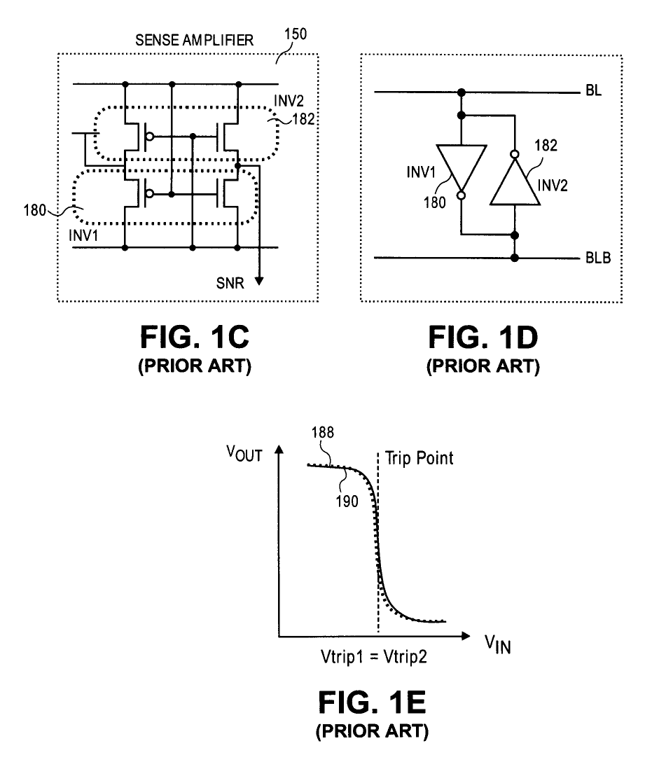

### DETAILED DESCRIPTION

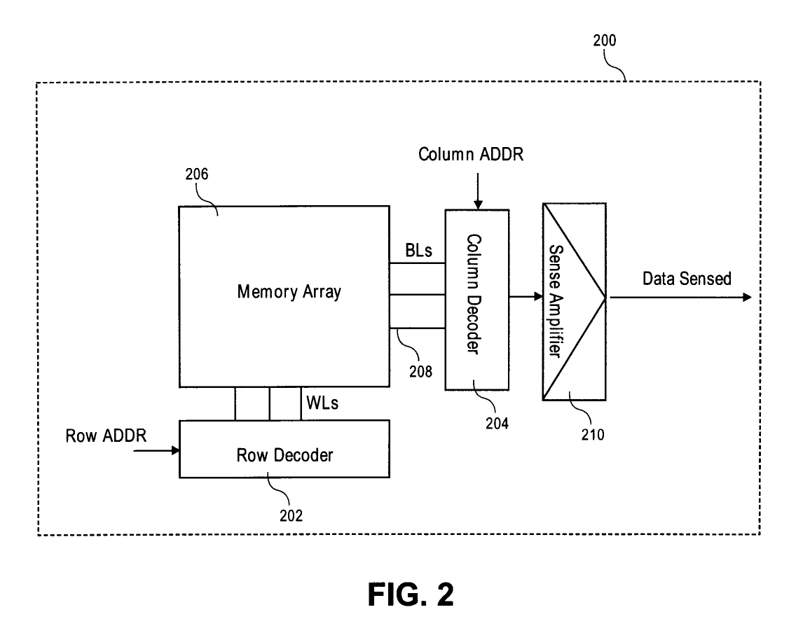

Example embodiments of the present invention may include a memory array communicatively coupled to sense amplifiers comprising asymmetrical circuitry coupled to bit line(s) and bit line bar(s). FIG. 2 is block diagram illustrating an example embodiment of a memory array device 200. The memory array device 200 includes a row decoder 202 and a column decoder 204 coupled to a memory array 206. In this embodiment, the bit lines 208 are coupled to a sense amplifier 210 via the column decoder 204. In one embodiment, the sense amplifier 210 may include asymmetrical circuitry configured to sense asymmetrical variations of voltages (corresponding to a stored “1” or “0”) associated with memory cells (not shown) of the memory array 206. This and other example embodiments may include a capability to accurately read previously deemed unreadable memory cells, thus effectively increasing the yield of usable memory.

In various embodiments, the asymmetrical circuitry may be implemented using various semiconductor devices of different characteristics, such as transistors having a different channel width (W) to channel length (L) ratio (i.e., (W/L)). Example embodiments of the invention may provide a flexibility of the reference voltages of a memory device by pre-charging bit lines and bit line bars, and/or provide a flexibility of the reference voltages for sensing the status of voltage level of bit lines or bit line bars. In some embodiments, the power consumption of a memory device may be reduced by not requiring a separate power supply or a pre-charge voltage generation circuit for generating a bit line or bit line bar pre-charge voltage. In some embodiments, the charge needed to allow the sensing of memory cell status may be reduced due to the change in the pre-charging voltage. Accordingly, the data retention time may be extended and the power consumed by frequent refreshment of memory data may be reduced.

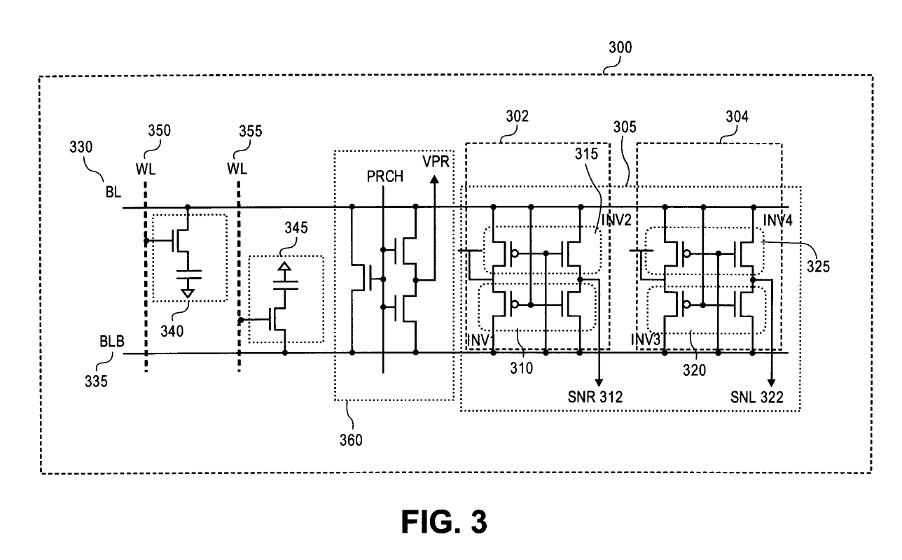

FIG. 3 illustrates an example embodiment of a memory device 300 that may be included in a memory array device 200. In this embodiment, the memory device 300 includes a memory cell 340, a memory cell 345, a pre-charge circuit 360, and a sense amplifier circuit 305. The memory cell 340 may be written by selectively enabling the word line (WL) 350 and may be read via the bit line (BL) 330. Similarly, the memory cell 345 may be written by selectively enabling the word line (WL) 355 and may be read via the bit line bar (BLB) 335. Pre-charge circuit 360 may be used to control the pre-charge of BL and BLB through the control of PRCH terminal and pre-charge the two lines to pre-charge reference voltage VPR.

In one example embodiment, the sense amplifier circuit 305 includes a sense amplifier 302 and a sense amplifier 304. Each of these two sense amplifiers 302 and 304 may be asymmetrical with respect to amplifying signals from BL and BLB. In one embodiment, the sense amplifier 302 may include two cross-coupled inverters 310 (INV1) and 315 (INV2), and the sense amplifier 304 may include another two cross-coupled inverters 320 (INV3) and 325 (INV4). In another embodiment, an inverter may include a PMOS (P-type) transistor and an NMOS (N-type) transistor having their gate terminals coupled together. One or more asymmetric sense amplifiers may be provided with two or more inverters with different characteristics, such as different transfer characteristic functions or different electrical characteristics. In one embodiment, the inverter 310 may have a different transfer (or amplifying) characteristic function from that of the inverter 315, and the inverter 320 may have a different transfer (or amplifying) characteristic function from that of the inverter 325. For example, the trip point of the inverter pair 310 and 315 and/or the inverter pair 320 and 325 may not be identical due to the different channel width to channel length ratio of the PMOS transistors or the different channel width to channel length ratio of the NMOS transistors. In another embodiment, the PMOS transistor of the inverter 310 has different electrical characteristics from those of the PMOS transistor of the inverter 315. For example, the threshold voltage of the PMOS transistor of the inverter 310 may be larger than that of the PMOS transistor of the inverter 315, which results in a larger logic threshold voltage of the inverter 310. Thus, in various embodiments, an asymmetric configuration of the sense amplifier may be obtained by respectively varying the physical dimensions of each inverter.

The sense amplifier 302 may be controlled by an enablement line SNR 312, and the sense amplifier 304 may be controlled by an enablement line SNL 322. The sense amplifier circuit 305 may be coupled to a pair of bit lines (e.g., a BL 330 and a BLB 335) and may sense the signals on the BL 330 and the BLB 335. In this example, the memory cell 340 and the memory cell 345 are respectively coupled to the BL 330 and the BLB 335, and respectively controlled by a WL 350 and a WL 355. The BL 330 and the BLB 335 are coupled to the pre-charge circuit 360, which is controlled by pre-charging enablement line PRCH and coupled to pre-charge reference voltage VPR.

In one example, sense amplifier 302, controlled by the SNR 312, may be used to read the memory cell 340 from the BL 330, and the sense amplifier 304, controlled by the SNL 322, may used to read the memory cell 345 from the BLB 335. In some examples, the two enablement lines SNR 312 and SNL 322 may be independently asserted. However, the SNR 312 and the SNL 322 may be simultaneously asserted to read the memory cell 340 and the memory cell 345 at the same time. Under this operation mode, the memory cell 340 and the memory cell 345 may store complementary values.

In another example embodiment, the sense amplifier circuit 305 may include one of the sense amplifiers, either the sense amplifier 302 or the sense amplifier 304. The sense amplifier circuit 305 may then sense a status of one of the bit line or the bit line bar at one time. For example as illustrated in FIG. 3, the sense amplifier circuit 305 includes one sense amplifier 302 with an asymmetric circuitry—that is, the transfer characteristic function of the inverter 310 is different from that of the inverter 315. The memory cell 340 and the memory cell 345 are coupled to the bit line (BL) 330 and the bit line bar (BLB) 335, respectively. The sense amplifier 302 may either read the memory cell 340 via the bit line (BL) 330 or read the memory cell 345 via the bit line bar (BLB) 335 depending on the transfer characteristic function of the inverter 310 and the inverter 315. For example, if the trip point of the inverter 310 is lower than that of the inverter 315, the sense amplifier 302 may access the memory cell 340. However, the sense amplifier 302 may access the memory cell 345 if the trip point of the inverter 310 is higher than that of the inverter 315.

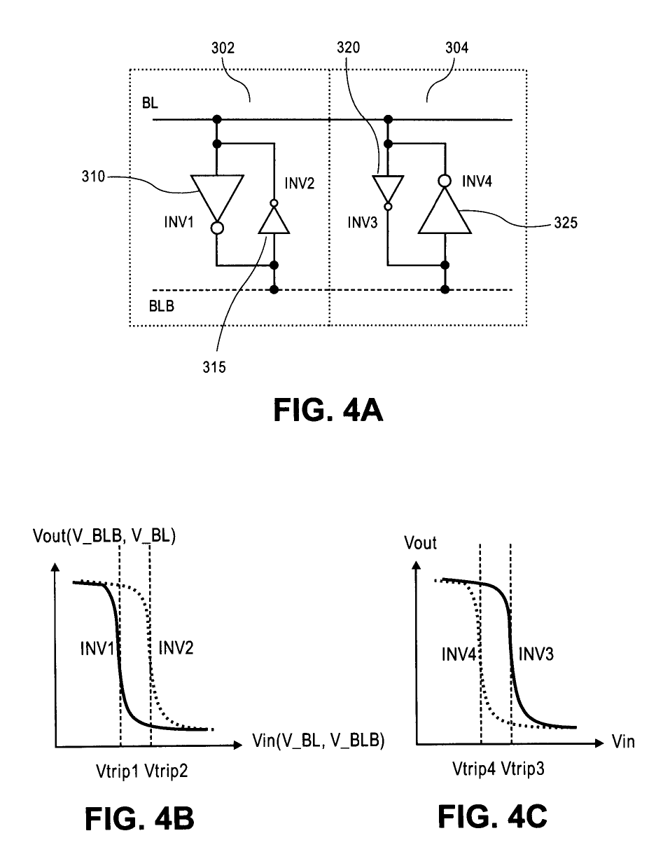

Various configurations may be used for the sense amplifier circuit 305 to provide an asymmetric structure. FIG. 4(a) illustrates a logic block diagram of one embodiment of the sense amplifiers 302 and 304 of FIG. 3. The sense amplifier 302 includes the inverter 310 and the inverter 315 cross-coupled with each other, and the sense amplifier 304 may have an inverter 320 and an inverter 325 cross-coupled with each other.

FIG. 4(b) illustrates an example of the transfer characteristic functions of the inverter 310 and the inverter 315. Referring to FIG. 4(b), the left curve is for the inverter 310 (INV1) and the right curve is for the inverter 315 (INV2). In this example, the trip point (Vtrip1) for the inverter 310 is lower than the trip point (Vtrip2) for the inverter 315. In other words, the inverter 310 is more “drivable” than the inverter 315, meaning that the inverter 310 may drive more loads than the inverter 315.

FIG. 4(c) illustrates an example embodiment of the transfer characteristic functions of an inverter 320 and an inverter 325. Referring to FIG. 4(c), the left curve is for the inverter 325 (INV4) and the right curve is for the inverter 320 (INV3). In this example, the trip point (Vtrip4) for the inverter 325 is lower than the trip point (Vtrip3) for the inverter 320. In other words, the inverter 325 is more “drivable” than the inverter 320, meaning that the inverter 325 may drive more load than the inverter 320.

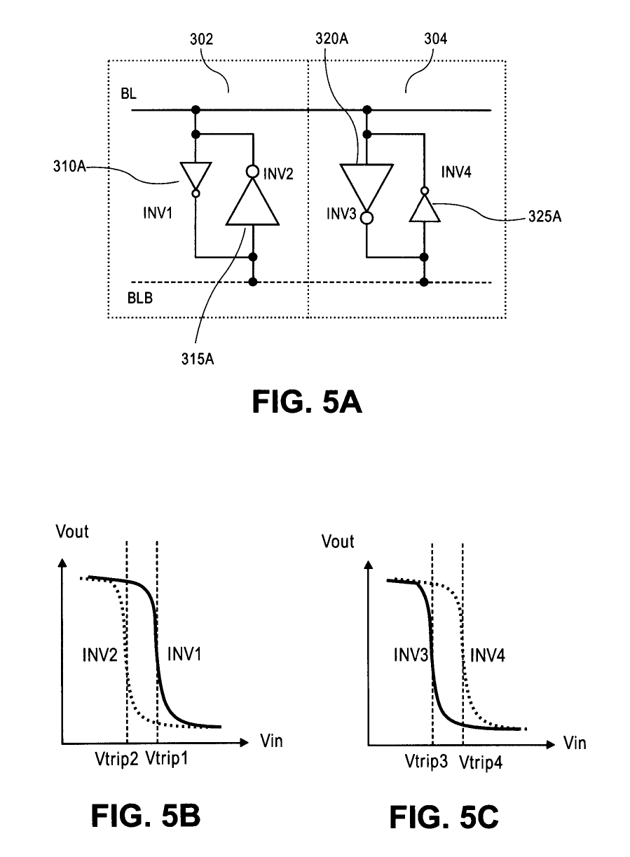

A second configuration of the sense amplifier circuit 305 in FIG. 3 is conceptually similar to the first configuration, but with a reversed asymmetry for each of the two sense amplifiers, as shown in FIGS. 5(a)-(c). FIG. 5(a) illustrates an exemplary block diagram of this configuration. Referring to FIG. 5(a), the sense amplifier 302 may have an inverter 310a and an inverter 315a cross-coupled with each other, and the sense amplifier 304 may have an inverter 320a and an inverter 325a cross-coupled with each other. FIG. 5(b) illustrates an example of the transfer characteristic functions of the inverter 310a and the inverter 315a. Referring to FIG. 5(b), the left curve is for the inverter 315a (INV) and the right curve is for the inverter 310a (INV1). In this example, the trip point (Vtrip2) for the inverter 315a is lower than the trip point (Vtrip1) for the inverter 310a. In other words, the inverter 315a is more “drivable” than the inverter 310a.

FIG. 5(c) illustrates an example of the transfer characteristic functions of the inverter 320a and the inverter 325a. Referring to FIG. 5(c), the left curve is for the inverter 320a (INV3) and the right curve is for the inverter 325a (INV4). In this example, the trip point (Vtrip3) for the inverter 320a is lower than the trip point (Vtrip4) for the inverter 325a. In other words, the inverter 320a is more “drivable” than the inverter 325a.

Depending on the memory circuit design and reference voltage levels, various configurations of one or more sense amplifiers may be used. In one example embodiment, the configuration of a sense amplifier and the transfer characteristic functions of the inverters may be adjusted based on various considerations, including the level of VPR. In many examples, flexibility of the level of VPR may be provided by using one or more sense amplifiers with an asymmetric design. In some examples, VPR may deviate from VDD/2 or a designed pre-charging reference voltage under various conditions to facilitate the circuit's functionality based on the design or characteristics of the sense amplifier circuit. For example, the VPR may be adjusted based on the characteristics of the sense amplifier due to variations in the manufacturing process, materials, or operating conditions. In some other example embodiments, the sense amplifiers or their characteristics may be designed and/or adjusted based on the VPR level provided in order to adjust the performance or operational characteristics of the memory devices. For example, if VPR is or approximates VDD, according to one example, the sense amplifiers or their characteristics may be designed or adjusted to vary the voltage level sensing characteristics, as illustrated with reference to transfer characteristic functions of FIGS. 4(b), 4(c), 5(b), and 5(c).

In one example embodiment, a configuration may be selected using a V_{increase}-V_{decrease} comparison. For example, when the memory cell 340 of FIG. 3 stores a level of voltage representing a logic “1,” it may generate a small voltage increase, V_{increase}, on BL 330 over VPR. Similarly, when the memory cell 340 stores a level of voltage representing a logic “0,” it may generate a small voltage decrease, V_{decrease}, on BL 330 from VPR. If V_{increase} is smaller than V_{decrease}, a sense amplifier of a memory device may use a configuration that is the same or similar to what is illustrated in FIGS. 4(a)-4(c). If V_{increase} is greater than V_{decrease}, a sense amplifier of a memory device may use a configuration that is the same or similar to what is illustrated in FIGS. 5(a)-5(c).

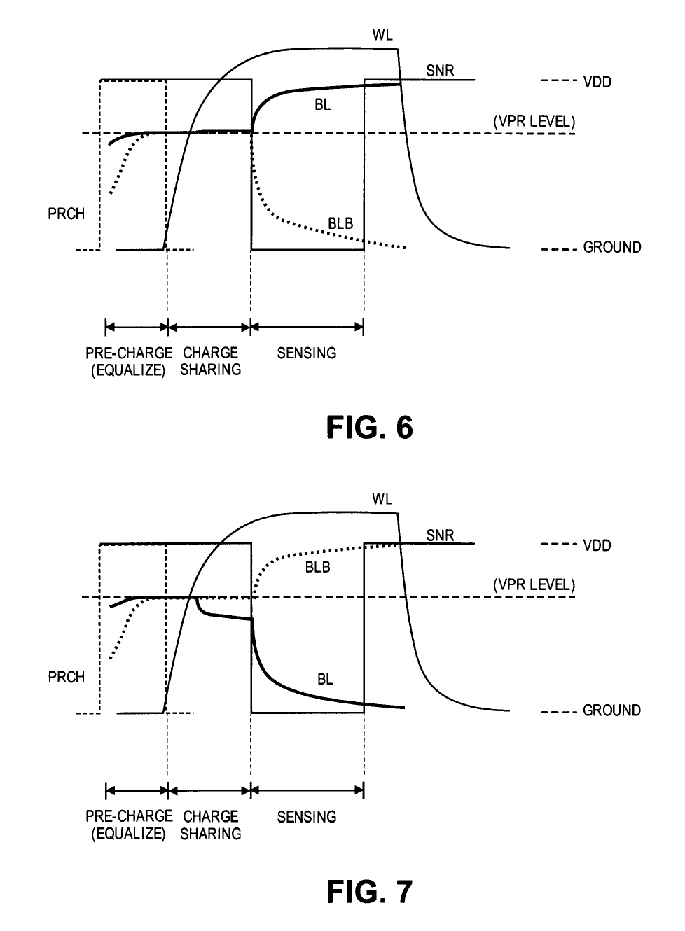

The operations of examples of sensing amplifiers consistent with the invention are illustrated below. In one example, VPR may be set to a level higher than VDD/2, such as somewhere between VDD/2 and VDD. As an illustrative example, the memory cell 340 of FIG. 3 may store a voltage level representing a logic “1” using a sense amplifier similar to what is described and illustrated with reference to FIGS. 4(a)-4(c) when V_{increase} is less than V_{decrease}. FIG. 6 illustrates an exemplary waveform for illustrating the sense amplifier operation. Referring to FIG. 6, a read operation of a memory device may have three phases: pre-charge (equalize), charge sharing, and sensing phases. In one example, a level of VPR between a ground level and a VDD level and higher than VDD/2 may be used. During the pre-charge phase, the level of both BL and BLB are pre-charged to VPR. During the charge-sharing phase, the word lines are activated to allow the BL and/or the BLB to share the charges (or be affected by a voltage level) stored in the corresponding memory cells. After charge sharing, the voltage level on the BL may become slightly higher than the VPR, in other words, a small voltage increase, V_{increase}, is generated, while the voltage on the BLB is near or at the VPR level.

In one embodiment, to amplify the difference between the BL and the BLB levels, a more drivable inverter, such as the inverter 310 in FIG. 4(a), may be used with the BL to push the voltage level on the BLB down to a lower level. The lowered voltage level at the BLB input may then result in the inverter 315 pulling up the voltage level on the BL up toward VDD. Accordingly, near the end of the sensing phase, a logical “1” status may be read out from the BL. In this embodiment, the asymmetric sense amplifier may provide an effective solution to distinguish the voltage difference in the BL and the BLB with providing flexible levels of the pre-charge reference voltage.

FIG. 7 illustrates an exemplary waveform for illustrating the sense amplifier operation. In this embodiment, the memory cell 340 of FIG. 3 stores a voltage level representing a logic “0.” Referring to FIG. 7, after charge sharing, the BL voltage level may become lower than the VPR, in other words, a small voltage decrease, V_{decrease}, is generated, while the BLB voltage level may be at or near the VPR. Thus, the inverter 310 with its gate coupled to the BL has a lower input voltage than the inverter 315 with its gate coupled to the BLB. Using the asymmetrical configuration of the sense amplifier 302 illustrated above in FIG. 4(a), the inverter 310 is more “drivable” than the inverter 315. However, by designing the trip point, the inverter 315 will not pull down the voltage level of the BLB. In some examples, this asymmetrical configuration may offer more flexible ranges for Vtrip1 and Vtrip2. For example, both Vtrip1 and Vtrip2 may be higher than the BL voltage level sampled after charge sharing but lower than VPR 360. In this example, inverter 315 may push the BL voltage level toward ground. And with the lower level at the BL as its input, inverter 310 may pull the BLB voltage level up toward VDD. Accordingly, near the end of the sensing phase, a logical “0” status may be read out from the BL.

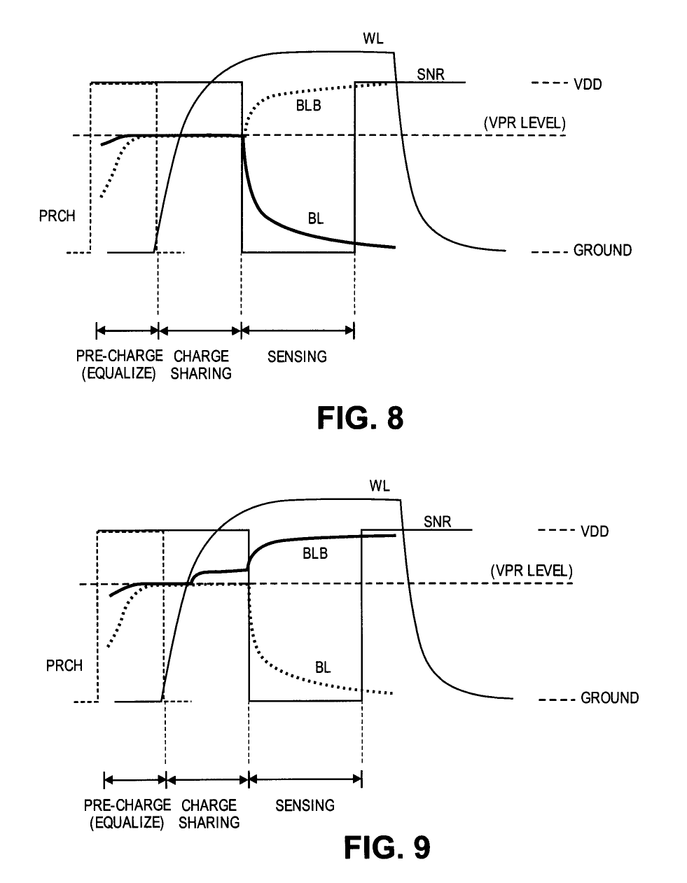

The sense amplifier may also have a configuration that is similar to or same as the configuration illustrated in FIG. 5(a)-5(c) when V_{increase} is greater than V_{decrease}. FIG. 8 illustrates exemplary BL and BLB waveforms when the memory cell 340 of FIG. 3 stores a logic “0” (i.e. V_{decrease} is generated). FIG. 9 illustrates exemplary BL and BLB waveforms when the memory cell 340 stores a logic “1” (i.e. V_{increase} is generated). Although the above examples illustrate the sensing amplifier operations of a memory cell when the VPR is higher VDD/2, the sensing amplifier operations of a memory cell may be similarly explained when the VPR is lower than VDD/2.

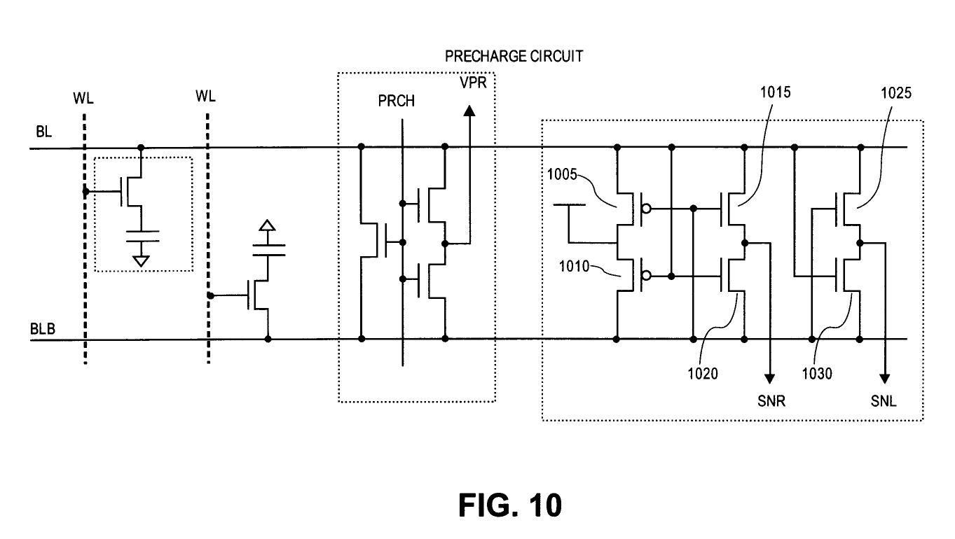

FIG. 10 illustrates an example of providing an asymmetric sense amplifier by sharing some of the transistors. Referring to FIG. 10, a PMOS transistor 1005 and a PMOS transistor 1010 may be used in common by two sets of asymmetric sense amplifiers. In one example, the PMOS transistor 1005 and an NMOS transistor 1015 may form a first inverter, and the PMOS transistor 1010 and an NMOS transistor 1020 may form a second inverter. The two cross-coupled first and second inverters may form a first sense amplifier. Additionally, the PMOS transistor 1005 and an NMOS transistor 1025 may form a third inverter, and the PMOS transistor 1010 and an NMOS transistor 1030 may form a fourth inverter. The two cross-coupled third and fourth inventers may form a second sense amplifier. In some examples, the common-transistor configuration may reduce the number of transistors needed for sense amplifier circuit(s) and may reduce the chip space or area occupied by a memory device.

One or both sets of sense amplifiers may be designed to have an asymmetric structure. For example, NMOS transistors 1015 and 1020 may have different characteristics, such as different transfer characteristic functions (e.g., different trip point of the inverters) or different electrical characteristics (e.g., different threshold voltages of the inverters). In one example, the drive strength (i.e. the channel width to the channel length ratio) of the transistor 1015, (W/L)₁₀₁₅, and the drive strength of the transistor 1020, (W/L)₁₀₂₀ may be designed to have a certain physical relationship. For example, the ratio of (W/L)₁₀₁₅/(W/L)₁₀₂₀ may range from 0.25 to 4 or even from 0.1 to 10, depending on various factors such as the device design, transistor thresholds, device applications, etc. The ratio of (W/L)₁₀₁₅/(W/L)₁₀₂₀ may be 2/3 in one example. Similarly, NMOS transistors 1025 and 1030 may have different characteristics, such as different transfer characteristic functions. The drive strength of transistor 1025, (W/L)₁₀₂₅, and the drive strength of transistor 1030, (W/L)₁₀₃₀ may be designed to have a certain physical relationship. In one example embodiment, the ratio of (W/L)₁₀₂₅/(W/L)₁₀₃₀ may range from 0.25 to 4 or even from 0.1 to 10, depending on various factors such as the device design, transistor thresholds, device applications, etc. The ratio of (W/L)₁₀₂₅/(W/L)₁₀₃₀ may be 3/2 in one example.

Additionally, the ratio of (W/L)₁₀₁₅/(W/L)₁₀₂₀ and the ratio of (W/L)₁₀₂₅/(W/L)₁₀₃₀ may be designed to have a certain physical relationship or be approximately the same in one example. In particular, the ratio of the drive strength of NMOS 1015 to the drive strength of NMOS 1020 may equal to the ratio of the drive strength of NMOS 1030 to the drive strength of NMOS 1025. For example, when the ratio of (W/L)₁₀₁₅/(W/L)₁₀₂₀ is 2/3, the ratio of (W/L)₁₀₂₅/(W/L)₁₀₃₀ may be 3/2. However, the ratios for various parameters illustrated above are exemplary and other ratios and combinations of various ratios may be used depending on various factors such as the device design, transistor thresholds, device applications, etc. Additionally, transistor thresholds may be designed independently or in combination with the W/L ratios to achieve similar results. In other words, the W/L ratio of each transistor may be varied to produce certain characteristics of the inverters and asymmetry or symmetry of each sense amplifier.

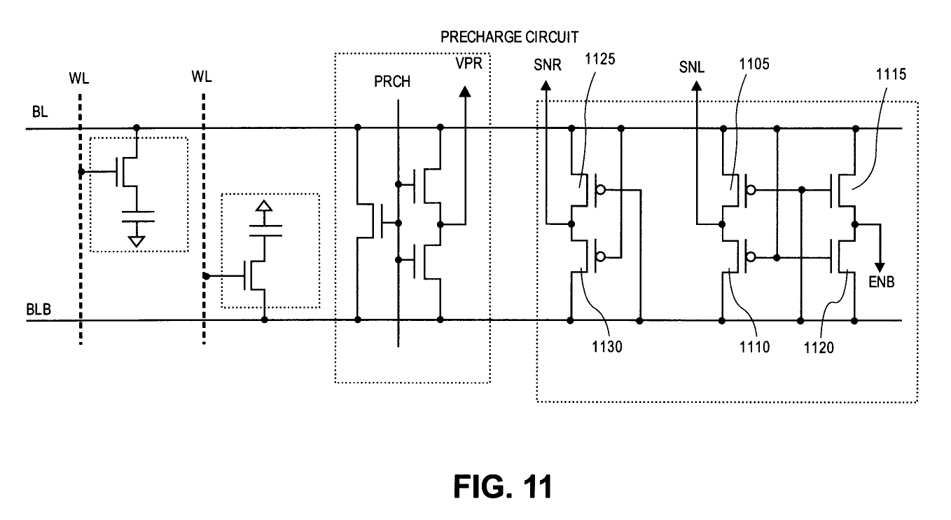

FIG. 11 illustrates another example of providing an asymmetric sense amplifier by using some of the transistors in common. Referring to FIG. 11, NMOS transistors 1115 and 1120 may be used in common by two sets of asymmetric sense amplifiers. In one example, the NMOS transistor 1115 and a PMOS transistor 1105 may form a first inverter, and the NMOS transistor 1120 and a PMOS transistor 1110 may form a second inverter. The two cross-coupled first and second inverters may form a first sense amplifier. Additionally, the NMOS transistor 1115 and a PMOS transistor 1125 may form a third inverter, and the NMOS transistor 1120 and a PMOS transistor 1130 may form a fourth inverter. The two cross-coupled third and fourth inventers may form a second sense amplifier. In some examples, the common-transistor configuration may reduce the number of transistors needed for sense amplifier circuit(s) and may reduce the chip space or area occupied by a memory device. To provide different characteristics for the two sets of sense amplifiers, such as different transfer characteristic functions, the first set of PMOS transistors 1105 and 1110 may have a different configuration from the second set of PMOS transistors 1125 and 1130.

One or both sets of sense amplifiers may be designed to have an asymmetric structure. For example, PMOS transistors 1105 and 1110 may have different characteristics, such as different transfer characteristic functions (e.g., different trip point of the inverters) or different electrical characteristics (e.g., different threshold voltages of the inverters). In one example, the drive strength of the transistor 1105, (W/L)₁₁₀₅, and the drive strength of the transistor 1110, (W/L)₁₁₁₀ may be designed to have a certain relationship. For example, the ratio of (W/L)₁₁₀₅/(W/L)₁₁₁₀ may range from 0.25 to 4 or even from 0.1 to 10, depending on various factors such as the device design, transistor thresholds, device applications, etc. The ratio of (W/L)₁₁₀₅/(W/L)₁₁₁₀ may be 2/3 in one example. Similarly, PMOS transistors 1125 and 1130 may have different characteristics, such as different transfer characteristic functions. In one example embodiment, the drive strength of the transistor 1125, (W/L)₁₁₂₅, and the drive strength of the transistor 1130, (W/L)₁₁₃₀ may be designed to have certain physical relationship. For example, the ratio of (W/L)₁₁₂₅/(W/L)₁₁₃₀ may range from 0.25 to 4 or even from 0.1 to 10, depending on various factors such as the device design, transistor thresholds, device applications, etc. The ratio of(W/L)₁₁₂₅/(W/L)₁₁₃₀ may be 3/2 in one example embodiment.

Additionally, the ratio of (W/L)₁₁₀₅/(W/L)₁₁₁₀ and the ratio of (W/L)₁₁₂₅/(W/L)₁₁₃₀ may be designed to have a certain physical relationship or be approximately the same in one example embodiment. However, the ratios for various parameters illustrated above are exemplary and other ratios and combinations of various ratios may be used depending on various factors such as the device design, transistor thresholds, device applications, etc. Additionally, transistor thresholds may be designed independently or in combination with the W/L ratios to achieve similar results. In other words, the W/L ratio of each transistor may be varied to produce certain characteristics of the inverters and asymmetry or symmetry of each sense amplifier.

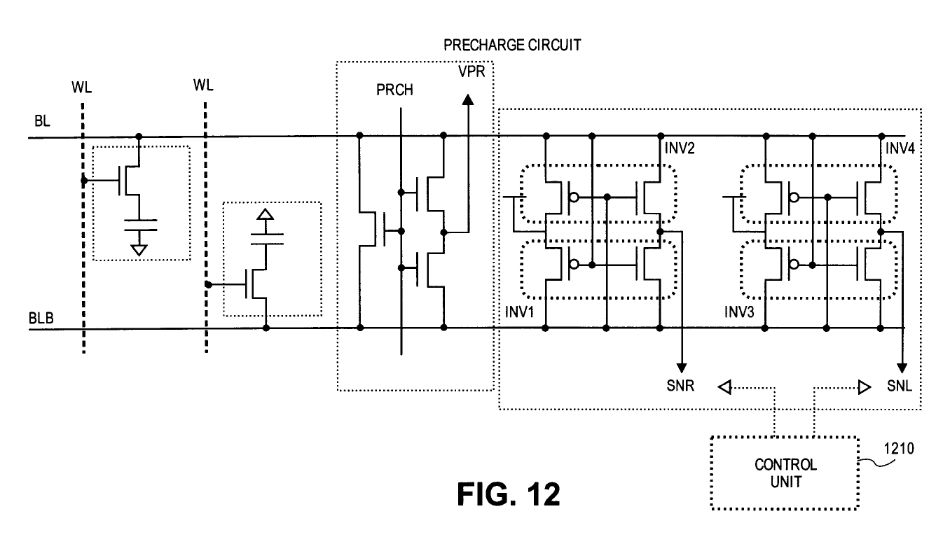

FIG. 12 illustrates an example of a circuit for controlling the enabling of sense amplifiers. Referring to FIG. 12, SNR and SNL may be controlled by a control unit 1210 to control the activation of one or both of the sense amplifiers by means of various methods. In one example embodiment, a fuse box set may be used as a control unit. During the power-up or after blowing the fuse(s), SNR 312 and SNL 322 or one of them may be enabled. In another example embodiment, a metal wire may be used to control the activation of the sense amplifiers. In other example embodiments, an automatic detecting unit may be used to automatically detect which sense amplifier is needed to be activated.

According to an embodiment of the invention, the two asymmetric sense amplifiers may operate independently with two individual separate enablement lines, such as SNR and SNL shown in FIG. 3, 10, or 11. In some examples, only one of these two enablement lines will be asserted at a time. In other examples, the memory may be configured so that the memory cell 340 and the memory cell 345 with reference to FIG. 3 always contain complementary values. In one example, the two cells may be read out at the same time, and SNR and SNL may be asserted simultaneously. In this example, the two cells may be coupled to two separate word lines and two sense amplifiers, one or both of which may be asymmetric and may be activated simultaneously. The characteristics of the two sense amplifiers may affect the combined effect of the two sense amplifiers on the BL and BLB signals.

From the foregoing, it may be seen that the present invention is directed to a memory device having a sense amplifier that may be configured asymmetrically or operate asymmetrically. It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

What is claimed is:

1. A memory device comprising:
a first memory cell and a second memory cell, wherein the first memory cell comprises a first transistor coupled to a bit line and the second memory cell comprises a second transistor coupled to a bit line bar;
a first word line and a second word line, wherein the first transistor and the second transistor include a first gate terminal and a second gate terminal coupled to and controlled by the first word line and the second word line respectively; and
a first sense amplifier coupled to the bit line and the bit line bar, wherein the first sense amplifier has an asymmetric configuration and is configured to sense a status of at least one of the bit line and the bit line bar.

2. The memory device of claim 1, wherein the first sense amplifier comprises a first inverter and a second inverter, the first inverter and the second inverter being cross-coupled, the input of the first inverter being coupled to the bit line and the output of the first inverter being coupled to the bit line bar, and the input of the second inverter being coupled to the bit line bar and the output of the second inverter coupled to the bit line.

3. The memory device of claim 2, wherein the first inverter and the second inverter each include a P-type transistor and an N-type transistor, and the first inverter and the second inverter are configured to have different transfer characteristic functions based on a different channel width to channel length ratio of one of the P-type or N-type transistors associated with the first inverter and the channel width to channel length ratio of the corresponding P-type or N-type transistors associated with the second inverter.

4. The memory device of claim 3, wherein the channel width to channel length ratio of one of the P-type or N-type transistors associated with the first inverter divided by the channel width to channel length ratio of the corresponding P-type or N-type transistors associated with the second inverter is between 0.1 and 10.

5. The memory device of claim 3, wherein the threshold voltage of one of the P-type or the N-type transistors associated with the first inverter varies from that of the threshold voltage of the corresponding P-type or N-type transistors associated with the second inverter.

6. The memory device of claim 1 further comprising a second sense amplifier coupled to the bit line and the bit line bar, the second sense amplifier being configured to sense a status of at least one of the bit line and the bit line bar.

7. The memory device of claim 6, wherein the second sense amplifier has an asymmetric configuration or a symmetric configuration.

8. The memory device of claim 7, wherein the second sense amplifier comprises a third inverter and a fourth inverter, the third inverter and the fourth inverter being cross-coupled, the input of the third inverter being coupled to the bit line and the output of the third inverter being coupled to the bit line bar, and the input of the fourth inverter being coupled to the bit line bar and the output of the fourth inverter coupled to the bit line.

9. The memory device of claim 8, wherein the third inverter and the fourth inverter each include a P-type transistor and an N-type transistor, and the third inverter and the fourth inverter are configured to have different transfer characteristic functions based on a different channel width to channel length ratio of one of the P-type or N-type transistors associated with the third inverter and the channel width to channel length ratio of the corresponding P-type or N-type transistors associated with the fourth inverter.

10. The memory device of claim 9, wherein the first inverter includes a first P-type transistor and a first N-type transistor, the third inverter includes a second P-type transistor and the first N-type transistor, the second inverter includes a third P-type transistor and a second N-type transistor, and the fourth inverter includes a fourth P-type transistor and the second N-type transistor.

11. The memory device of claim 9, wherein the first inverter includes a first P-type transistor and a first N-type transistor, the third inverter includes the first P-type transistor and a second N-type transistor, the second inverter includes a second P-type transistor and a third N-type transistor, and the fourth inverter includes the second P-type transistor and a fourth N-type transistor.

12. The memory device of claim 9, wherein the channel width to channel length ratio of one of the P-type or N-type transistors associated with the third inverter divided by the channel width to channel length ratio of the corresponding P-type or N-type transistor associated with the fourth inverter is between 0.1 and 10.

13. The memory device of claim 9, wherein the second sense amplifier is symmetric, the third inverter and the fourth inverter having identical transfer characteristic functions based on an identical channel width to channel length ratio of one of the P-type or N-type transistor associated with the third inverter and the corresponding P-type or N-type transistors associated with the fourth inverter.

14. The memory device of claim 6, wherein the first sense amplifier and the second sense amplifier are configured to simultaneously activate the first memory cell and the second memory cell respectively.

15. The memory device of claim 6, further comprising a control unit coupled to the first amplifier and the second sense amplifier, the control unit configured to control the activation of one or both of the first sense amplifier and the second sense amplifier.

16. A memory array device comprising:
a memory cell array comprising memory cells and coupled to a first decoder and a second decoder, each memory cell including a bit line and a bit line bar; and
a sense amplifier circuit coupled to the first decoder and the bit line and the bit line bar, the sense amplifier circuit including a first sense amplifier having an asymmetric configuration to sense a status of at least one of the bit line and the bit line bar of a memory cell.

17. The memory array device of claim 16, wherein the sense amplifier circuit further comprises a second sense amplifier coupled to the bit line and the bit line bar, the second sense amplifier configured to sense a status of at least one of the bit line and the bit line bar.

18. The memory array device of claim 16, wherein the first sense amplifier comprises a first inverter and a second inverter, the first inverter and the second inverter being cross-coupled, each of the first inverter and the second inverter including a P-type transistor and an N-type transistor and the first inverter and the second inverter being configured to have different transfer characteristic functions based on a different channel width to channel length ratio of one of the P-type or N-type transistors associated with the first inverter and the corresponding P-type or N-type transistors associated with the second inverter.

19. The memory device of claim 18, wherein the threshold voltage of one of the P-type or the N-type transistors associated with the first inverter is different from that of the corresponding P-type or N-type transistors associated with the second inverter.

20. The memory array device of claim 17, wherein the second sense amplifier comprises a third inverter and a fourth inverter, the third inverter and the fourth inverter being cross-coupled, each of the third inverter and the fourth inverter including a P-type transistor and an N-type transistor and the third inverter and the fourth inverter being configured to have identical or different transfer characteristic functions based on a channel width to channel length ratio of one of the P-type or N-type transistors associated with the third inverter and the channel width to channel length ratio of the corresponding P-type or N-type transistors associated with the fourth inverter.

21. The memory device of claim 20, wherein the first inverter includes a first P-type transistor and a first N-type transistor, the third inverter includes a second P-type transistor and the first N-type transistor, the second inverter includes a third P-type transistor and a second N-type transistor, and the fourth inverter includes a fourth P-type transistor and the second N-type transistor.

22. The memory device of claim 20, wherein the first inverter includes a first P-type transistor and a first N-type transistor, the third inverter includes the first P-type transistor and a second N-type transistor, the second inverter includes a second P-type transistor and a third N-type transistor, and the fourth inverter includes the second P-type transistor and a fourth N-type transistor.

22. The memory array device of claim 17, wherein the first sense amplifier and the second sense amplifier are configured to activate different memory cells simultaneously.

23. The memory device of claim 17, further comprising a control unit coupled to the first amplifier and the second sense amplifier, the control unit configured to control the activation of one or both of the first sense amplifier and the second sense amplifier.
